(19) United States
(12) Patent Application Publication
(10) Pub. No.: US 2016/0297921 A1
(43) Pub. Date: Oct. 13, 2016

(54) CURABLE EPOXY COMPOSITION, FILM, LAMINATED FILM, PREPREG, LAMINATE, CURED ARTICLE, AND COMPOSITE

(71) Applicant: ZEON CORPORATION, Tokyo (JP)

(72) Inventors: Natsuko Shindo, Tokyo (JP); Makoto Fujimura, Tokyo (JP)

(73) Assignee: ZEON CORPORATION, Tokyo (JP)

(21) Appl. No.: 14/777,910

(22) PCT Filed: Mar. 19, 2014
(86) PCT No.: PCT/JP2014/057498

§ 371 Date: Sep. 17, 2015

(30) Foreign Application Priority Data
Mar. 22, 2013 (JP) 2013-060280

(51) Int. Cl. C08G 59/42; H05K 1/03; C08J 5/24; C08L 63/08; C08G 59/38; C08J 5/18

(52) U.S. Cl. CPC C08G 59/42; C08G 59/38; C08J 5/18; C08J 5/24; C08L 63/08; H05K 1/0353; C08J 2363/08; C08L 2203/20

(57) ABSTRACT

A curable epoxy composition comprising a polyvalent epoxy compound (A) which has a condensed polycyclic structure and/or biphenyl structure, an aromatic and/or alicyclic polyvalent glycidyl ester compound (B), and an active ester compound (C) is provided. According to the present invention, a curable epoxy composition which can form an electrical insulating layer which is excellent in desmearing ability, electrical characteristics, and heat resistance can be provided.

### TECHNICAL FIELD

The present invention relates to a curable epoxy composition, film, laminated film, prepreg, laminate, cured article, and composite.

### BACKGROUND ART

Along with the pursuit of smaller sizes, increased functions, and faster communications in electronic equipment, further higher densities of the circuit boards which are used for the electronic equipment have been sought. To meet such demands for higher densities, circuit boards are being made multilayered. Such multilayer circuit boards are, for example, formed by taking an inside layer board which is comprised of an electrical insulating layer and a conductor layer which is formed on its surface, laminating an electrical insulating layer over it, forming a conductor layer over this electrical insulating layer, and further repeating this lamination of an electrical insulating layer and formation of a conductor layer.

As the material for forming the electrical insulating layer of such multilayer circuit boards, in general ceramics and thermosetting resins are being used. Among these, as thermosetting resins, epoxy resins are being widely used since they are excellent in the point of the balance of economy and performance.

As an epoxy resin material for forming an electrical insulating layer, for example, Patent Document 1 discloses an epoxy resin composition which contains an epoxy resin, a curing agent constituted by an active ester compound, a curing accelerator, and a filler and which has a content of the active ester compound of 118 to 200 parts by weight with respect to 100 parts by weight of the epoxy resin. It describes that according to the composition, a cured product which is excellent in dielectric characteristics (for example, an electrical insulating layer) can be formed.

In this regard, in the above multilayer circuit board, the conductor layers are connected with each other through via holes which are provided in the electrical insulating layers. In the formation of via holes, an electrical insulating layer is formed with a hole for via hole by laser processing, then metal plating, but before that, desmearing is performed to remove the resin residue (smears) which formed in the laser processing and remains on the lower conductor layer or electrical insulating layer. The desmearing is performed by, for example, dipping the multilayer board in which the hole for via hole are formed in a solution of a chemical oxidizing agent such as potassium permanganate or potassium dichromate to dissolve away the smears in the hole. If the desmearing ability is insufficient and the desmearing is not sufficiently secured, even if metal plating the via hole, the smears are liable to prevent conduction between the upper conductor layer and lower conductor layer from being sufficiently secured.

### PRIOR ART DOCUMENTS

### Patent Documents

Patent Document 1: Japanese Patent Publication No. 2011-32296A

### SUMMARY OF THE INVENTION

### Problem to be Solved by the Invention

Therefore, the present inventors engaged in studies and clarified that when using the above epoxy resin composition according to Patent Document 1 to form an electrical insulating layer of a multilayer printed circuit board, the heat resistance, desmearing ability, etc. are insufficient.

An object of the present invention is to provide a curable epoxy composition which can form an electrical insulating layer which is excellent in desmearing ability, electrical characteristics, and heat resistance and a film, laminated film, prepreg, laminate, cured article, and composite which are obtained using this.

### Means For Solving the Problem

The present inventors engaged in intensive research for achieving the above object and as a result discovered that according to a curable epoxy composition comprising a polyvalent epoxy compound which has a condensed polycyclic structure and/or biphenyl structure and an aromatic and/or alicyclic polyvalent glycidyl ester compound in combination, an electrical insulating layer which has the desired characteristics can be obtained and thereby completed the present invention.

That is, according to the present invention, there are provided
[1] A curable epoxy composition comprising a polyvalent epoxy compound (A) which has a condensed polycyclic structure and/or biphenyl structure (however, excluding an aromatic and/or alicyclic polyvalent glycidyl ester compound (B)), an aromatic and/or alicyclic polyvalent glycidyl ester compound (B), and an active ester compound (C),
[2] The curable epoxy composition according to [1] wherein the ratio of content of the aromatic and/or alicyclic polyvalent glycidyl ester compound (B) is 5 to 75 wt % in the total 100 wt % of epoxy compounds which are used,
[3] The curable epoxy composition according to [1] or [2] wherein the polyvalent epoxy compound (A) which has a condensed polycyclic structure and/or biphenyl structure is a phenol novolac type epoxy compound which has a condensed polycyclic structure and/or biphenyl structure,
[4] The curable epoxy composition according to any one of [1] to [3] wherein the aromatic and/or alicyclic polyvalent glycidyl ester compound (B) is an o-phthalic acid diglycidyl ester and/or terephthalic acid diglycidyl ester,
[5] The curable epoxy composition according to any one of [1] to [4] further comprising an alicyclic olefin polymer which contains an aromatic ring and/or hetero atom and does not have reactivity with an epoxy group,
[6] A film which is comprised of the curable epoxy composition according to any one of [1] to [5],
[7] A laminated film having an adhesive layer which is comprised of the curable epoxy composition according to any one of [1] to [5] and a platable layer which is comprised of a platable layer-use resin composition,
[8] A prepreg which is comprised of the film according to [6] or laminated film according to [7], and a fiber substrate,
[9] A laminate obtained by laminating, on a base material, the film according to [6], the laminated film according to [7], or the prepreg according to [8],
[10] A cured article obtained by curing the curable epoxy composition according to any one of [1] to [5], the film according to [6], the laminated film according to [7], the prepreg according to [8], or the laminate according to [9],
[11] A composite obtained by forming a conductor layer on the surface of the cured article according to [10], and
[12] A substrate for an electronic material including, as a component material, the cured article according to [10] or the composite according to [11].

### Effects of the Invention

According to the present invention, there are provided a curable epoxy composition which enables the formation of an electrical insulating layer which is excellent in desmearing ability, electrical characteristics, and heat resistance and a film, laminated film, prepreg, laminate, cured article, and composite which are obtained using the same.

### DESCRIPTION OF EMBODIMENTS

The curable epoxy composition of the present invention is a composition which comprises a polyvalent epoxy compound (A) which has a condensed polycyclic structure and/or biphenyl structure (however, excluding an aromatic and/or alicyclic polyvalent glycidyl ester compound (B)), an aromatic and/or alicyclic polyvalent glycidyl ester compound (B), and an active ester compound (C),

The curable epoxy composition of the present invention has, as one major characteristic, the combination of a polyvalent epoxy compound (A) which has a condensed polycyclic structure and/or biphenyl structure (below, sometimes abbreviated as the “polyvalent epoxy compound (A)”) and an aromatic and/or alicyclic polyvalent glycidyl ester compound (B) (below, sometimes abbreviated as the “polyvalent glycidyl ester compound (B)”). A cured resin which is obtained by curing a polyvalent epoxy compound (A) by an active ester compound (C) which acts as a curing agent is excellent in electrical characteristics and heat resistance, but in the present invention, along with the polyvalent epoxy compound (A), further a polyvalent glycidyl ester compound (B) is used. Thus, the electrical insulating layer comprised of the obtained cured resin has excellent electrical characteristics etc. and is excellent in desmearing ability as well. Below, the present invention will be explained in detail.

[Polyvalent Epoxy Compound (A)]

The polyvalent epoxy compound (A) which has a condensed polycyclic structure and/or biphenyl structure used in the present invention is a compound which has at least two epoxy groups (oxirane ring) in a molecule and has at least one of a condensed polycyclic structure and biphenyl structure. Among these as well, an epoxy compound which has a condensed polycyclic structure and/or biphenyl structure and which has at least two glycidyl ether structures in a molecule is preferable. As the epoxy compound which has a condensed polycyclic structure and/or biphenyl structure and has at least two glycidyl ether structures in a molecule, a phenol novolac type epoxy compound which has a condensed polycyclic structure and/or biphenyl structure is preferable from the viewpoint of the heat resistance and electrical characteristics. Note that, the polyvalent epoxy compound excludes the later explained polyvalent glycidyl ester compound (B).

The “condensed polycyclic structure” means a structure which is comprised of two or more single rings condensed together (condensed rings). The rings which form the condensed polycyclic structure may be aliphatic rings or aromatic rings and, further, may contain hetero atoms. The number of the condensed rings is not particularly limited, but from the viewpoint of raising the heat resistance and mechanical strength of the obtained cured resin, two or more rings are preferable. In practice, the upper limit is about 10 rings. As the condensed polycyclic structure, for example, a dicyclopentadiene structure, naphthalene structure, fluorene structure, anthracene structure, phenanthrene structure, triphenylene structure, pyrene structure, ovalene structure, etc. may be mentioned. In the obtained cured resin, the condensed polycyclic structure usually forms the main chain of the resin, but may also be present at the side chains.

The “biphenyl structure” means a structure in which two benzene rings are bonded by a single bond. A biphenyl structure, like the condensed polycyclic structure, usually forms the main chain of the resin in the obtained cured resin, but may also be present at the side chains.

As the polyvalent epoxy compound (A) used in the present invention, one which has a condensed polycyclic structure or biphenyl structure or one which has both of a condensed polycyclic structure and biphenyl structure is included, but from the viewpoint of raising the heat resistance and mechanical strength of the obtained cured resin, a polyvalent epoxy compound (A) which has a condensed polycyclic structure is preferable, while one which has a dicyclopentadiene structure is more preferable.

Further, as the polyvalent epoxy compound (A), when combining one which has a condensed polycyclic structure (including one which has a condensed polycyclic structure and biphenyl structure) and one which has a biphenyl structure, from the viewpoint of raising the heat resistance and electrical characteristics of the electrical insulating layer, the ratio of content of these is a weight ratio (polyvalent epoxy compound which has a condensed polycyclic structure/polyvalent epoxy compound which has a biphenyl structure) of usually suitably 3/7 to 7/3.

As a polyvalent epoxy compound (A), since a good curing reactivity can be obtained, one with an epoxy equivalent of usually 100 to 1500 equivalents, preferably 150 to 500 equivalents, is suitable.

Note that, in the present Description, “epoxy equivalent” is the number of grams of an epoxy compound which includes 1 gram equivalent of epoxy groups (g/eq) and can be measured in accordance with the method of JIS K 7236.

The polyvalent epoxy compound (A) used in the present invention can be suitably produced in accordance with a known method, but can also be obtained as a commercially available product.

As an example of the commercially available product of a polyvalent epoxy compound (A) which has a condensed polycyclic structure, a phenol novolac type epoxy compound which has a dicyclopentadiene structure, for example, product names “Epiclon HP7200L, Epiclon HP7200, Epiclon HP7200H, Epiclon HP7200HH, Epiclon HP7200 HH” (above made by DIC, “Epiclon” is a registered trademark), product name “Tactix558” (made by Huntsman Advanced Material, “Tactix” is a registered trademark), product names “XD-1000-1L, XD-1000-2L” (above, made by Nippon Kayaku); an epoxy compound which has a fluorene structure, for example, product names “Oncoat EX-1010, Oncoat EX-1011, Oncoat EX-1012, Oncoat EX-1020, Oncoat EX-1030, Oncoat EX-1040, Oncoat EX-1050, Oncoat EX-1051” (above made by Nagase & CO., LTD., “Oncoat” is a registered trademark), product names “Ogsol PG-100, Ogsol EG-200, Ogsol EG-250)” (above, made by Osaka Gas Chemical, “Ogsol” is a registered trademark); etc. may be mentioned. Further, an epoxy compound which has a polyphenol structure, for example, product names “1032H60, XY-4000” (above, made by Mitsubishi Chemical), etc. can also be used as a polyvalent epoxy compound (A).

As an example of a commercially available product of the polyvalent epoxy compound (A) which has a biphenyl structure, a phenol novolac type epoxy compound which has a biphenylaralkyl structure, for example, product names “NC3000-FH, NC3000-H, NC3000, NC3000-L, NC3100” (above made by Nippon Kayaku) etc. may be mentioned.

The above polyvalent epoxy compounds (A) can be used respectively alone or as two or more types mixed together.

(Polyvalent Glycidyl Ester Compound (B))

As the polyvalent glycidyl ester compound (B) in the present invention, an aromatic polyvalent glycidyl ester compound, alicyclic polyvalent glycidyl ester compound, or both an aromatic polyvalent glycidyl ester compound and alicyclic polyvalent glycidyl ester compound may be used.

The “aromatic polyvalent glycidyl ester compound” is a compound of an aromatic polyvalent carboxylic acid which has two or more carboxyl groups in a molecule where at least two carboxyl groups are glycidyl-esterified. Further, the “alicyclic polyvalent glycidyl ester compound” is a compound of an alicyclic polyvalent carboxylic acid which has two or more carboxyl groups in a molecule where at least two carboxyl groups are glycidyl-esterified.

As the polyvalent glycidyl ester compound (B), an aromatic polyvalent glycidyl ester compound is preferably used from the viewpoint of improving the electrical characteristics and desmearing ability in the obtained electrical insulating layer.

Further, as the polyvalent glycidyl ester compound (B), when combining the aromatic polyvalent glycidyl ester compound and alicyclic polyvalent glycidyl ester compound, the ratio of these is preferably a weight ratio (aromatic polyvalent glycidyl ester compound/alicyclic polyvalent glycidyl ester compound) of usually 2/8 to 8/2.

As the polyvalent glycidyl ester compound (B), since a good curing reactivity is obtained, one with an epoxy equivalent of usually 100 to 1500 equivalents, preferably 125 to 1000 equivalents, is suitable.

The polyvalent glycidyl ester compound (B) can be easily synthesized by a condensation reaction between an aromatic polyvalent carboxylic acid chloride or alicyclic polyvalent carboxylic acid chloride and glycidol, or a condensation reaction between an alkali salt of an aromatic polyvalent carboxylic acid or alicyclic polyvalent carboxylic acid and epichlorohydrin. From the viewpoint of better manifesting the effect of the present invention, usually the thus obtained polyvalent glycidyl ester compound (B) is suitably used, in the present invention, an alicyclic polyvalent glycidyl ester compound which is synthesized by partially or completely hydrogenating the aromatic rings of an aromatic polyvalent glycidyl ester compound or a diglycidyl ester resin of an aromatic polyvalent carboxylic acid or alicyclic polyvalent carboxylic acid by using a polycondensation reaction as the condensation reaction can be also used. From the above viewpoint, as the polyvalent glycidyl ester compound (B), the compound which is synthesized by hydrogenation, the resin which is synthesized by a polycondensation reaction, and the compound which is synthesized by a condensation reaction are high in industrial applicability in that order. Note that, the specific conditions etc. of the above reactions are generally known.

The aromatic polyvalent carboxylic acid is not particularly limited, but, for example, phthalic acid, isophthalic acid, terephthalic acid, 1,2-naphthalene dicarboxylic acid, 1,4-naphthalene dicarboxylic acid, 1,8-naphthalene dicarboxylic acid, 2,3-naphthalene dicarboxylic acid, 2,6-naphthalene dicarboxylic acid, 9,10-anthracene dicarboxylic acid, 4,4′-benzophenondicarboxylic acid, 2,2′-biphenyl dicarboxylic acid, 3,3′-biphenyl dicarboxylic acid, 4,4′-biphenyl dicarboxylic acid, 3,3′-biphenylether dicarboxylic acid, 4,4′-biphenylether dicarboxylic acid, 4,4′-binaphthyl dicarboxylic acid, hemimellitic acid, trimellitic acid, trimesic acid, 1,2,4-naphthalene tricarboxylic acid, 2,5,7-naphthalene tricarboxylic acid, mellophanic acid, prehnitic acid, pyromellitic acid, 3,3′,4,4′-benzophenone tetracarboxylic acid, 2,2′,3,3′-benzophenone tetracarboxylic acid, 2,3,3′,4′-benzophenone tetracarboxylic acid, 3,3′,4,4′-biphenyl tetracarboxylic acid, 2,2′,3,3′-biphenyl tetracarboxylic acid, 2,3,3′,4′-biphenyl tetracarboxylic acid, 4,4′-oxydiphthalic acid, 3,3′,4,4′-diphenylmethane tetracarboxylic acid, 1,4,5,8-naphthalene tetracarboxylic acid, 1,2,5,6-naphthalene tetracarboxylic acid, 2,3,6,7-naphthalene tetracarboxylic acid, anthracene tetracarboxylic acid, etc. may be mentioned.

The alicyclic polyvalent carboxylic acid is not particularly limited, but, for example, hexahydrophthalic acid, hexahydroisophthalic acid, hexahydroterephthalic acid, or other cyclohexane dicarboxylic acid; and tetrahydrophthalic acid, tetrahydroisophthalic acid, tetrahydroterephthalic acid, or other cyclohexene dicarboxylic acid; cyclohexadiene carboxylic acid; bicyclohexyl dicarboxylic acid; etc. may be mentioned.

The polyvalent glycidyl ester compound (B) can be obtained as a commercial product. For example, the o-phthalic acid glycidyl ester of product name “Denacol (registered trademark) EX-721” (made by Nagase Chemtex) etc.; the terephthalic acid diglycidyl ester of product name “Denacol (registered trademark) EX-711” (made by Nagase Chemtex) etc.; the hexahydrophthalic acid diglycidyl ester of product name “Epomik (registered trademark) R540” (made by Mitsui Chemicals), product name “AK-601” (made by Nippon Kayaku), etc.; may be mentioned.

As the polyvalent glycidyl ester compound (B), since it is excellent in curing reaction and can better improve the electrical characteristics and desmearing ability at the obtained electrical insulating layer, o-phthalic acid diglycidyl ester or terephthalic acid diglycidyl ester is preferably used, while o-phthalic acid diglycidyl ester is particularly preferable. The above polyvalent glycidyl ester compound (B) can be used respectively alone or as two or more types mixed together.

(Other Epoxy Compounds)

The curable epoxy composition of the present invention may suitably contain, in addition to the polyvalent epoxy compound and polyvalent glycidyl ester compound (B), any desired other epoxy compounds besides these epoxy compounds. As these other epoxy compounds, for example, an alicyclic epoxy compound, cresol novolac type epoxy compound, phenol novolac type epoxy compound, bisphenol A type epoxy compound, trisphenol type epoxy compound, tetrakis(hydroxyphenyl)ethane type epoxy compound, aliphatic chain epoxy compound, etc. may be mentioned. These may be suitably obtained as commercially available products.

In the total 100 wt % of the epoxy compounds used for the curable epoxy composition of the present invention, the ratio of content of the polyvalent epoxy compound (A) is preferably 25 wt % or more, more preferably 30 wt % or more, furthermore preferably 35 wt % or more, particularly preferably 45 wt % or more. The upper limit is usually 95 wt %. The ratio of content of the polyvalent glycidyl ester compound (B) is preferably 75 wt % or less, more preferably 70 wt % or less, furthermore preferably 65 wt % or less, particularly preferably 55 wt % or less, while the lower limit is usually 5 wt %. The content of the other epoxy compounds is not particularly limited so long as the realization of the desired effect of the present invention is not obstructed, but usually 60 wt % or less is suitable. By making the amount of the epoxy compounds used in the above range, the effect of the present invention can be realized well.

(Active Ester Compound (C))

The active ester compound (C) used in the present invention may be one which has active ester groups, but in the present invention, a compound which has at least two active ester groups in its molecule is preferable. The active ester compound (C) acts as a curing agent for the epoxy compounds used in the present invention.

As the active ester compound (C), from the viewpoints of raising the heat resistance of the obtained electrical insulating layer etc., an active ester compound which is obtained by reacting a carboxylic acid compound and a hydroxy compound and/or thiol compound is preferable, an active ester compound which is obtained by reacting a carboxylic acid compound and one or more compounds selected from the group comprised of a phenol compound and naphthol compound is more preferable, and an aromatic compound which is obtained by reacting a carboxylic acid compound and an aromatic compound having a phenolic hydroxyl group and which has at least two active ester groups in a molecule is particularly preferable. The active ester compound (C) may be a linear one or multibranched one. If illustrating the case where the active ester compound (C) is derived from a compound which has at least two carboxylic acids in its molecule, when such a compound which has at least two carboxylic acids in its molecule contains an aliphatic chain, it is possible to raise the compatibility with the epoxy resin, while when it has an aromatic ring, it is possible to raise the heat resistance.

As specific examples of the carboxylic acid compound for forming an active ester compound (C), benzoic acid, acetic acid, succinic acid, maleic acid, itaconic acid, phthalic acid, isophthalic acid, terephthalic acid, pyromellitic acid, etc. may be mentioned. Among these as well, from the viewpoint of raising the heat resistance of the obtained electrical insulating layer, succinic acid, maleic acid, itaconic acid, phthalic acid, isophthalic acid, and terephthalic acid are preferable, phthalic acid, isophthalic acid, and terephthalic acid are particularly preferable, and isophthalic acid and terephthalic acid are furthermore preferable.

As specific examples of the hydroxy compound for forming the active ester compound (C), hydroquinone, resorcine, bisphenol A, bisphenol F, bisphenol S, phenol phthalein, methylated bisphenol A, methylated bisphenol F, methylated bisphenol S, phenol, o-cresol, m-cresol, p-cresol, catechol, α-naphthol, β- naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, fluoroglycine, benzenetriol, dicyclopentadienyl diphenol, phenol novolac, etc. may be mentioned. Among these as well, from the viewpoints of improving the solubility of the active ester compound (C) and raising the heat resistance of the obtained electrical insulating layer, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, dicyclopentadienyl diphenol, and phenol novolac are preferable, dihydroxybenzophenone, trihydroxybenzophenone, tetrahydroxybenzophenone, dicyclopentadienyl diphenol, and phenol novolac are more preferable, and diyclopentadienyl diphenol and phenol novolac are furthermore preferable.

The method of production of the active ester compound (C) is not particularly limited. It may be produced by a known method. For example, it may be obtained by a condensation reaction between the carboxylic acid compound and hydroxy compound.

In the present invention, as the active ester compound (C), for example, an aromatic compound which has an active ester group disclosed in Japanese Patent Publication No. 2002-12650A or a polyfunctional polyester disclosed in Japanese Patent Publication No. 2004-277460A or a commercially available product may be used. As the commercially available product, for example, product names “EXB9451, EXB9460, EXB9460S, Epiclon HPC-8000-65T” (above, made by DIC, “Epiclon” is a registered trademark), product name “DC808” (made by Japan Epoxy Resin), product name “YLH1026” (made by Japan Epoxy Resin), etc. may be mentioned.

In the curable epoxy composition of the present invention, the amount of the active ester compound (C) is preferably 20 to 140 parts by weight with respect to the 100 parts by weight of total of the epoxy compounds used (that is, the total of the polyvalent epoxy compound (A), polyvalent glycidyl ester compound (B), and other epoxy compounds which are used in accordance with need), more preferably 40 to 125 parts by weight, furthermore preferably 60 to 110 parts by weight. Further, the equivalent ratio, in the curable epoxy composition, of the epoxy compound and active ester compound (C) used (total number of epoxy groups in epoxy compound used (that is, the total number of epoxy groups of the polyvalent epoxy compounds (A), the epoxy groups of the polyvalent glycidyl ester compound (B), and the epoxy groups of other epoxy compounds which are used according to need) with respect to the total number of active ester groups in the active ester compound (C)) (amount of epoxy groups/amount of active ester groups) is preferably 0.5 to 1.25, more preferably 0.7 to 1.1, furthermore preferably 0.8 to 1.05. By making the amount of the active ester compound (C) in the above range, the obtained electrical insulating layer can be improved in electrical characteristics and heat resistance and the coefficient of thermal expansion can be kept small.

(Other Ingredients)

The curable epoxy composition of the present invention may further suitably contain, to an extent not interfering with the expression of the effect of the present invention, other ingredients such as described below other than the polyvalent epoxy compound (A), polyvalent glycidyl ester compound (B), and active ester compound (C).

By mixing a filler into the curable epoxy composition of the present invention, it is possible to make the obtained cured resin low in linear expansion. As that filler, either of a known inorganic filler and organic filler can be used, but an inorganic filler is preferable. As specific examples of an inorganic filler, calcium carbonate, magnesium carbonate, barium carbonate, zinc oxide, titanium oxide, magnesium oxide, magnesium silicate, calcium silicate, zirconium silicate, hydrated alumina, magnesium hydroxide, aluminum hydroxide, barium sulfate, silica, talc, clay, etc. may be mentioned. Note that, the filler used may be surface treated in advance by a silane coupling agent etc.

The content of the filler in the curable epoxy composition of the present invention is not particularly limited, but converted to solid content is usually 30 to 90 wt %.

Further, by mixing, into the curable epoxy composition of the present invention, an alicyclic olefin polymer which contains aromatic rings and/or hetero atoms and not having reactivity to an epoxy group, it is possible to improve the flexibility of the later explained film or laminate film which is obtained by using the composition and improve the handling ability without lowering the storage stability of the composition. This alicyclic olefin polymer is one which does not have reactivity with respect to an epoxy group, so therefore substantially does not contain any functional group which has reactivity to an epoxy group. Here, “substantially does not contain any functional group which has reactivity to an epoxy group” means the alicyclic olefin polymer does not contain any functional group which has reactivity with respect to an epoxy group to an extent where expression of the effect of the present invention is obstructed. As a functional group which has reactivity with an epoxy group, a group which has a structure which can react with an epoxy group to form a covalent bond may be mentioned, for example, a primary amino group, secondary amino group, mercapto group, carboxyl group, carboxylic acid anhydride group, hydroxyl group, and epoxy group and other hetero atom-containing functional group which reacts with an epoxy group to form a covalent bond may be mentioned.

The above alicyclic olefin polymer can, for example, be easily obtained by suitably combining and polymerizing, in accordance with a known method, an alicyclic olefin monomer (a) which does not contain a hetero atom but contains an aromatic ring, an alicyclic olefin monomer (b) which does not contain an aromatic ring but contains a hetero atom, an alicyclic olefin monomer (c) which contains both an aromatic ring and hetero atom, and a monomer (d) which does not contain either an aromatic ring and hetero atom and can copolymerize with the alicyclic olefin monomers (a) to (c). The obtained polymer may be further hydrogenated.

As specific examples of the alicyclic olefin monomer (a), 5-phenyl-bicyclo[2.2.1]hept-2-ene, 1,4-methano-1,4,4a,5,10,10a-hexahydroanthracene, tetracyclo[6.5.0.1^{2,5}.0^{8,13}]trideca-3,8,10,12-tetraene (also referred to as “1,4-methano-1,4,4a,9a-tetrahydrofluorene”, below, abbreviated as “MTF”), tetracyclo[6.6.0.1^{2,5}.1^{8,13}]tetradeca-3,8,10,12-tetraene (also referred to as “1,4-methano-1,4,4a,5,10,10a-hexahydroanthracene”), 8-phenyl-tetracyclo[4.4.0.1^{2,5}.1^{7,10}]dodec-3-ene, etc. may be mentioned.

As specific examples of the alicyclic olefin monomer (b), 8-methyl-8-methoxycarbonyltetracyclo[4.4.0.1^{2,5}.1^{7,10}]dodec-3-ene, 5-methoxy-carbonyl-bicyclo[2.2.1]hept-2-ene, 5-cyano-bicyclo[2.2.1]hept-2-ene, 5-methyl-5-methoxycarbonyl-bicyclo[2.2.1]hept-2-ene; 5-methoxycarbonylbicyclo[2.2.1]hept-2-ene, 5-ethoxycarbonylbicyclo[2.2.1]hept-2-ene, 5-methyl-5-methoxycarbonylbicyclo[2.2.1]hept-2-ene, 5-methyl-5-ethoxycarbonylbicyclo[2.2.1]hept-2-ene, bicyclo[2.2.1]hept-5-enyl-2-methylpropionate, bicyclo[2.2.1]hept-5-enyl-2-methyloctanate; 5-cyanobicyclo[2.2.1]hept-2-ene, N-methylbicyclo[2.2.1]hept-2-ene-5,6-dicarboxylic acid imide, N-(2-ethylhexyl)bicyclo[2.2.1]hept-2-ene-5,6-dicarboxylic acid imide (below, abbreviated as “NEHI”), 8-methoxycarbonyltetracyclo[4.4.1.1^{2,5}.1^{7,10}.0]-dodec-3-ene, 8-methyl-8-methoxycarbonyltetracyclo[4.4.1.1^{2,5}.1^{7,10}.0]-dodec-3-ene, bicyclo[2.2.1]hept-2-ene-5,6-dicarboxylic acid anhydride (below, abbreviated as “NDCA”) etc. may be mentioned.

As specific examples of the alicyclic olefin monomer (c), N-(4-phenyl)-(5-norbornene-2,3-dicarboxyimide) (below, abbreviated as “NBPI”), N-(4-methylphenyl)-(5-norbornene-2,3-dicarboxyimide), 2-(4-methoxyphenyl)-5-norbornene, 2-benzyloxycarbonyl-5-norbornene, etc. may be mentioned.

As specific examples of the alicyclic olefin monomer (d), bicyclo[2.2.1]hept-2-ene (common name: norbornene), 5-ethylidene-bicyclo[2.2.1]hept-2-ene (below, abbreviated as “EdNB”), or other norbornenes; tricyclo[4.3.0.1^{2,5}]deca-3,7-diene (cation name: dicyclopentadiene), or other dicyclopentadienes; tetracyclo[4.4.0.1^{2,5}.1^{7,10}]dodec-3-ene (common name: tetracyclododecene, below abbreviated as “TCD”), or other tetracyclododecenes; ethylene, propylene, or other α-olefins having 2 to 20 carbon atoms; 1,4-hexadiene, or other nonconjugated dienes etc. may be mentioned.

In the curable epoxy composition of the present invention, the content of the alicyclic olefin polymer which contains an aromatic ring and/or hetero atom and does not have reactivity with respect to an epoxy group is not particularly limited, but it is usually 1 to 50 parts by weight with respect to a total 100 parts by weight of the epoxy compounds used, preferably 2 to 35 parts by weight.

The curable epoxy composition of the present invention may, as desired, contain a curing accelerator. The curing accelerator is not particularly limited, but, for example, an aliphatic polyamine, aromatic polyamine, secondary amine, tertiary amine, acid anhydride, imidazole derivative, organic acid hydrazide, dicyan diamide, and their derivatives, urea derivatives, etc. may be mentioned. Among these as well, an imidazole derivative is particularly preferable.

The imidazole derivative is not particularly limited so long as a compound which has an imidazole structure, but, for example, 2-ethylimidazole, 2-ethyl-4-methylimidazole, bis-2-ethyl-4-methylimidazole, 1-methyl-2-ethylimidazole, 2-isopropylimidazole, 2,4-dimethylimidazole, 2-heptadecylimidazole, or other alkyl-substituted imidazole compounds; 2-phenylimidazole, 2-phenyl-4-methylimidazole, 1-benzyl-2-methylimidazole, 1-benzyl-2-ethylimidazole, 1-benzyl-2-phenylimidazole, benzimidazole, 2-ethyl-4-methyl-1-(2′-cyanoethyl)imidazole, or other imidazole compounds which are substituted by aryl groups, aralkyl groups or other hydrocarbon groups which contain cyclic structures etc. may be mentioned. These may be used alone or as two or more types combined.

In the curable epoxy composition of the present invention, the amount of the curing accelerator is usually 0.1 to 10 parts by weight with respect to the total 100 parts by weight of the epoxy compounds used, preferably 0.5 to 8 parts by weight.

Furthermore, the curable epoxy composition of the present invention may suitably have mixed into it, for the purpose of improving the flame retardance of the electrical insulating layer obtained, for example a halogen-based flame retardant, phosphoric acid ester-based flame retardant, or other flame retardant which is mixed into general resin compositions for forming an electrical insulating film.

The curable epoxy composition of the present invention may suitably further contain, as desired, a flame retardant aid, heat resistance stabilizer, weather resistance stabilizer, antiaging agent, ultraviolet absorber (laser processability improving agent), leveling agent, antistatic agent, slip agent, antiblocking agent, anticlouding agent, lubricant, dye, natural oil, synthetic oil, wax, emulsion, magnetic substance, dielectric characteristic adjuster, toughness agent, or other known ingredients.

The method of production of the curable epoxy composition of the present invention is not particularly limited. The above ingredients may be mixed in as they are or may be mixed in the state dissolved or dispersed in an organic solvent. Part of the above ingredients may be dissolved or dispersed in an organic solvent to prepare a composition and the remaining ingredients mixed with that composition.

(Film)

The film of the present invention is a shaped article obtained by forming the above-mentioned curable epoxy composition of the present invention into a sheet shape or film shape.

When forming the curable epoxy composition of the present invention into a sheet shape or film shape to obtain a shaped article, it is preferable to obtain it by coating, spraying, or casting the curable epoxy composition of the present invention while, in accordance with need, adding an organic solvent, then drying.

As the support which is used at this time, a resin film or metal foil etc. may be mentioned. As the resin film, a polyethylene terephthalate film, polypropylene film, polyethylene film, polycarbonate film, polyethylene naphthalate film, polyacrylate film, nylon film, etc. may be mentioned. Among these films, due to the excellent heat resistance, chemical resistance, peelability, etc., a polyethylene terephthalate film or polyethylene naphthalate film is preferable. As the metal foil, a copper foil, aluminum foil, nickel foil, chromium foil, gold foil, silver foil, etc. may be mentioned.

The thickness of the sheet shape or film shape shaped article is not particularly limited, but from the viewpoint of the work efficiency etc., it is usually 1 to 150 μm, preferably 2 to 100 μm, more preferably 5 to 80 μm.

As the method of coating the curable epoxy composition of the present invention, dip coating, roll coating, curtain coating, die coating, slit coating, gravure coating, etc. may be mentioned.

Note that, in the present invention, as the sheet shape or film shape shaped article, the curable epoxy composition of the present invention is preferably in an uncured or semicured state. Here, “uncured” means the state where when dipping a shaped article in a solvent which is able to dissolve the epoxy compounds which are used for preparation of the composition (that is, polyvalent epoxy compound (A), polyvalent glycidyl ester compound (B), and other epoxy compounds which are used according to need), substantially all of the epoxy compound are dissolved. Further, “semicured” means the state of being partially cured to an extent enabling further curing upon heating, preferably a state where parts of the epoxy compounds which are used for preparation of the composition (specifically, amounts of 7 wt % or more and amounts where parts remain) is dissolved in a solvent able to dissolve the epoxy compound or a state where the volume after dipping the shaped article in the solvent for 24 hours is 200% or more of the volume before dipping (swelling rate).

Further, the curable epoxy composition of the present invention may be coated on a support, then dried if desired. The drying temperature is preferably made a temperature of an extent whereby the curable epoxy composition of the present invention does not cure. It is usually 20 to 300° C., preferably 30 to 200° C. If the drying temperature is too high, the curing reaction proceeds too much and the obtained shaped article is liable to no longer become the uncured or semicured state. Further, the drying time is usually 30 seconds to 1 hour, preferably 1 minute to 30 minutes.

The thus obtained film of the present invention is used in a state adhered to the support or peeled off from the support.

(Laminated Film)

The laminated film of the present invention has an adhesive layer which is comprised of the above-mentioned curable epoxy composition and a platable layer which is comprised of a platable layer-use resin composition.

The platable layer is not particularly limited, but from the viewpoint of improving the laminated film in electrical characteristics, waterproofness, and heat resistance, one where at least 50 wt % of the resin comprising that layer is comprised of an alicyclic olefin polymer is preferable. As a platable layer-use resin composition for forming such a platable layer, usually an alicyclic olefin polymer which has a polar group and one which contains a curing agent is preferable.

The alicyclic olefin polymer which has a polar group is not particularly limited. One which has an alicyclic structure constituted by a cycloalkane structure or cycloalkene structure etc. may be mentioned, but from the viewpoint of the mechanical strength, heat resistance, etc., one which has a cycloalkane structure is preferable. Further, as the polar group which is contained in the alicyclic olefin polymer, an alcoholic hydroxyl group, phenolic hydroxyl group, carboxyl group, alkoxyl group, epoxy group, glycidyl group, oxycarbonyl group, carbonyl group, amino group, carboxylic anhydride group, sulfonic group, phosphoric group, etc. may be mentioned. Among these as well, a carboxyl group, carboxylic anhydride group, and phenolic hydroxyl group are preferable, while a carboxylic anhydride group is more preferable.

The curing agent which is included in the platable layer-use resin composition is not particularly limited so long as one which can for a cross-linked structure in the alicyclic olefin polymer which has a polar group by heating. It is possible to use a curing agent which is mixed in a resin composition for use in forming a general electrical insulating film. As the curing agent, it is preferable to use a compound which has two or more functional groups which can form bonds by reaction with the polar groups of the used alicyclic olefin polymer which has a polar group as the curing agent.

For example, as the curing agent which is suitably used when using an alicyclic olefin polymer which has a carboxyl group, carboxylic anhydride group, or phenolic hydroxy group as the alicyclic olefin polymer which has a polar group, a polyepoxy compound, polyisocyanate compound, polyamine compound, polyhydrazide compound, aziridine compound, basic metal oxides, organometallic halide, etc. may be mentioned. These may be used alone or may be used in two or more types. Further, it is also possible to jointly use these compounds and peroxides as a curing agent.

Among these, as a curing agent, since the reactivity with the polar groups of the alicyclic olefin polymer which has a polar group is moderate and the handling of the platable layer-use resin composition becomes easy, a polyvalent epoxy compound is preferable. A glycidyl ether type epoxy compound or alicyclic polyvalent epoxy compound is particularly preferably used.

In the platable layer-use resin composition, the amount of the curing agent is preferably 1 to 100 parts by weight with respect to 100 parts by weight of the alicyclic olefin polymer which has a polar group, more preferably 5 to 80 parts by weight, furthermore preferably 10 to 50 parts by weight. By making the amount of the curing agent in the above range, the mechanical strength and electrical characteristics of the cured product which is obtained by curing the laminated film of the present invention can be improved.

Further, the platable layer-use resin composition used in the present invention may contain, in addition to the above ingredients, a hindered phenol compound or hindered amine compound.

The hindered phenol compound is a phenol compound which has at least one hindered structure which has a hydroxyl group and which does not have a hydrogen atom at the carbon atom of the β-position of the hydroxyl group in its molecule. As specific examples of the hindered phenol compound, 1,1,3-tris-(2-methyl-4-hydroxy-5-tert-butylphenyl)butane, 4,4′-butylidenebis-(3-methyl-6-tert-butylphenol), 2,2-thiobis(4-methyl-6-tert-butylphenol), n-octadecyl-3-(4′-hydroxy-3′,5′-di-tert-butylphenyl)propionate, tetrakis-[methylene-3-(3′,5′-di-tert-butyl-4′-hydroxyphenyl)propionate]methane, etc. may be mentioned.

The content of the hindered phenol compound in the platable layer-use resin composition is not particularly limited, but is preferably 0.04 to 10 parts by weight with respect to 100 parts by weight of the alicyclic olefin polymer which has a polar group, more preferably 0.3 to 5 parts by weight, furthermore preferably 0.5 to 3 parts by weight. By making the amount of the hindered phenol compound in the above range, it is possible to improve the mechanical strength of the cured product which is obtained by curing the laminated film of the present invention.

Further, the hindered amine compound is a compound which has at least one 2,2,6,6-tetraalkylpiperidine group which has a secondary amine or tertiary amine at the 4-position in its molecule. The number of carbons of the alkyl is usually 1 to 50. As the hindered amine compound, a compound which has at least one 2,2,6,6-tetramethylpiperidyl group which has a secondary amine or tertiary amine at the 4-position in its molecule is preferable. Note that, in the present invention, it is preferable to use both the hindered phenol compound and the hindered amine compound. By using these together, when treating the cured article which is obtained by curing a laminated film of the present invention to roughen its surface by using an aqueous solution of permanganate etc., even when the surface roughening treatment conditions change, it becomes possible to keep the cured article after surface roughening treatment as one low in surface roughness.

As specific examples of the hindered amine compound, bis(2,2,6,6-tetramethyl-4-piperidyl)sebacate, bis(1,2,2,6,6-pentamethyl-4-piperidyl)sebacate, 1-[2-{3-(3,5-di-tert-butyl-4-hydroxyphenyl)propionyloxy}ethyl]-4-{3-(3,5-di-tert-butyl-4-hydroxyphenyl)propionyloxy}-2,2,6,6-tetramethylpiperidine, 8-benzyl-7,7, 9,9-tetramethyl-3-octyl-1,2,3-triazaspiro[4,5]undecane-2,4-dione, etc. may be mentioned.

The amount of the hindered amine compound is not particularly limited, but is usually 0.02 to 10 parts by weight with respect to 100 parts by weight of the alicyclic olefin polymer which has a polar group, preferably 0.2 to 5 parts by weight, more preferably 0.25 to 3 parts by weight. By making the amount of the hindered amine compound in the above range, it is possible to improve the mechanical strength of the cured product which is obtained by curing the laminated film of the present invention.

Further, the platable layer-use resin composition used in the present invention may contain a curing accelerator in addition to the above ingredients. As the curing accelerator, a curing accelerator which is mixed into a general resin composition for electrical insulating film forming use may be used, but, for example, a curing accelerator similar to the above-mentioned curable epoxy composition of the present invention may be used. The amount of the curing accelerator in the platable layer-use resin composition may be suitably selected in accordance with the purpose of use, but is preferably 0.001 to 30 parts by weight with respect to 100 parts by weight of the alicyclic olefin polymer which has a polar group, more preferably 0.01 to 10 parts by weight, furthermore preferably 0.03 to 5 parts by weight.

Furthermore, the platable layer-use resin composition used in the present invention may contain a filler in addition to the above ingredients. As the filler, one similar to the filler which is used for the above-mentioned curable epoxy composition can be used. In the platable layer-use resin composition, the amount of the filler, converted to solid content, is usually 1 to 50 wt %, preferably 2 to 45 wt %, more preferably 3 to 35 wt %.

Further, the platable layer-use resin composition used in the present invention may suitably further contain, in addition to the above ingredients, in the same way as the above-mentioned curable epoxy composition of the present invention, a curing accelerator, flame retardant, flame retardant aid, heat resistance stabilizer, weather resistance stabilizer, antiaging agent, ultraviolet absorber (laser processability improving agent), leveling agent, antistatic agent, slip agent, antiblocking agent, anticlouding agent, lubricant, dye, natural oil, synthetic oil, wax, emulsion, magnetic substance, dielectric characteristic adjuster, toughness agent, or other known ingredients. The ratio of mixture of these optional ingredients may be suitably selected in a range not detracting from the object of the present invention.

The method of production of the platable layer-use resin composition used in the present invention is not particularly limited. The above ingredients can be mixed as they are or may be mixed in the state dissolved or dispersed in an organic solvent. Part of the above ingredients may be dissolved or dispersed in an organic solvent to prepare a composition and the remaining ingredients mixed with that composition.

The laminated film of the present invention is produced using such a platable layer-use resin composition and the above-mentioned curable epoxy composition of the present invention. Specifically, the laminated film of the present invention can for example be produced by the following two methods: (1) the method of production by coating, spraying, or casting the above-mentioned platable layer-use resin composition on a support, drying it as desired, then further coating or casting the above-mentioned curable epoxy composition on that and drying it if necessary and (2) the method of production by laminating a platable layer-use shaped article which is obtained by coating, spraying, or casting the above-mentioned platable layer-use resin composition on a support, drying it as desired, and forming this to a sheet shape or film shape and an adhesive layer-use shaped article which is obtained by coating, spraying, or casting the above-mentioned curable epoxy composition on a support, drying it if necessary, and forming this to a sheet shape or film shape and joining these shaped articles. Among these methods of production, since the process is simpler and the productivity is better, the method of production of the above (1) is preferable.

In the method of production of the above-mentioned (1), when coating, spraying, or casting the platable layer-use resin composition on the support and when coating, spraying, or casting the curable epoxy composition on the coated, sprayed, or cast platable layer-use resin composition or, in the method of production of the above-mentioned (2), when shaping the platable layer-use resin composition and the curable epoxy composition into sheet shapes or film shapes to obtain the platable layer-use shaped article and adhesive layer-use shaped article, it is preferable to coat, spray, or cast the platable layer-use resin composition or the curable epoxy composition on the support while adding an organic solvent as desired.

As the support which is used at this time, a resin film or metal foil etc. may be mentioned. As the resin film, a polyethylene terephthalate film, polypropylene film, polyethylene film, polycarbonate film, polyethylene naphthalate film, polyarylate film, nylon film, etc. may be mentioned. Among these films, from the viewpoint of the heat resistance, chemical resistance, peel property, etc., a polyethylene terephthalate film or polyethylene naphthalate film is preferable. As the metal foil, copper foil, aluminum foil, nickel foil, chrome foil, gold foil, silver foil, etc. may be mentioned. Note that, the surface roughness Ra of the support is usually 300 nm or less, preferably 150 nm or less, more preferably 100 nm or less.

The thicknesses of the platable layer-use resin composition and the curable epoxy composition in the method of production of the above-mentioned (1) and the thicknesses of the platable layer-use shaped article and adhesive layer-use shaped article in the method of production of the above-mentioned (2) are not particularly limited, but the thickness of the platable layer when made into a laminated film is preferably 1 to 10 μm, more preferably 1 to 8 μm, furthermore preferably 2 to 5 μm, while the thickness of the adhesive layer is preferably 10 to 100 μm, more preferably 10 to 80 μm, furthermore preferably 15 to 60 μm. If the thickness of the platable layer is too thin, when forming a conductor layer by electroless plating on a cured article which is obtained by curing the laminated film, the formability of the conductor layer is liable to end up falling, while if the thickness of the platable layer is too thick, the cured article which is obtained by curing the laminated film is liable to become larger in linear expansion. Further, if the thickness of the adhesive layer is too small, the wire embedding ability of the laminated film is liable to end up falling.

As the method of coating the platable layer-use resin composition and curable epoxy composition, dip coating, roll coating, curtain coating, die coating, slit coating, gravure coating, etc. may be mentioned.

Further, in the method of production of the above-mentioned (1), after the platable layer-use resin composition is coated, sprayed, or cast on the support or after the curable epoxy composition is coated, sprayed, or cast on the platable layer-use resin composition or, in the method of production of the above-mentioned (2), after the platable layer-use resin composition and the curable epoxy composition are coated on the supports, the compositions may be dried as needed. The drying temperature is preferably made a temperature of an extent where the platable layer-use resin composition and the curable epoxy composition will not cure and is normally 20 to 300° C., preferably 30 to 200° C. Further, the drying time is normally 30 seconds to 1 hour, preferably 1 minute to 30 minutes.

Note that, in the laminated film of the present invention, the platable layer and adhesive layer which form the laminated film are preferably in the uncured or semicured state. By making these the uncured or semicured state, it is possible to make the adhesive layer which forms the laminated film of the present invention high in adhesion.

(Prepreg)

The prepreg of the present invention is comprised of the above-mentioned film of the present invention or the laminated film of the present invention and a fiber base material.

As the fiber base material, a polyamide fiber, polyaramide fiber, polyester fiber, or other organic fiber or glass fiber, carbon fiber, or other inorganic fiber may be mentioned. Further, as the form of the fiber base material, a flat weave or twill weave or other woven fabric or nonwoven fabric etc. may be mentioned. The fiber base material has a thickness of preferably 5 to 100 μm, more preferably 10 to 50 μm. If too thin, the handling becomes difficult, while if too thick, the resin layer becomes relatively thin and its wire embedding ability sometimes becomes insufficient.

When the prepreg of the present invention is comprised of the above-mentioned film of the present invention and a fiber base material, the prepreg of the present invention can be produced by impregnating the curable epoxy composition of the present invention in a fiber base material. In this case, the method of impregnating the curable epoxy composition of the present invention in a fiber base material is not particularly limited, but to add an organic solvent to the curable epoxy composition of the present invention for adjusting the viscosity etc., the method of dipping the fiber base material in the curable epoxy composition to which the organic solvent is added, the method of coating or spraying the curable epoxy composition to which an organic solvent is added on a fiber base material, etc. may be mentioned. In the method of coating or spraying, it is possible to place the fiber base material on a support and coat or spray the curable epoxy composition to which the organic solvent is added on this. Note that, in the present invention, the sheet shape or film shape composite shaped article, in the same way as the above-mentioned sheet shape or film shape article, preferably contains the curable epoxy composition of the present invention in the uncured or semicured state.

Further, after impregnating the curable epoxy composition of the present invention in the fiber base material, it may be dried as desired. The drying temperature is preferably made a temperature of an extent where the curable epoxy composition of the present invention does not cure and is usually 20 to 300° C., preferably 30 to 200° C. If the drying temperature is too high, the curing reaction proceeds too much and the obtained composite shaped article is liable not to become uncured or semicured in state. Further, the drying time is usually 30 seconds to 1 hour, preferably 1 minute to 30 minutes.

Alternatively, when the prepreg of the present invention is comprised of the above-mentioned laminated film of the present invention and a fiber base material, the prepreg of the present invention preferably has an adhesive layer at one surface, a platable layer at the other surface, and a fiber base material at the inside. The method of production is not limited, but for example this can be produced by the following methods: (1) the method of stacking a curable epoxy composition film film with support and a platable layer-use resin composition film with a support to sandwich a fiber base material between them with the resin layer sides of the films facing each other and laminating them as desired under pressure, vacuum, heating, or other conditions; (2) the method of impregnating either the curable epoxy composition or platable layer-use resin composition in a fiber base material and drying it as required so as to prepare a prepreg and coating, spraying, or casting the other resin composition on this prepreg or stacking the other resin composition film with a support; or (3) the method of coating, spraying, or casting, either the curable epoxy composition or platable layer-use resin composition to a support to form a layer, placing a fiber base material over it, and further coating, spray, or casting the other resin composition over that to form a layer and drying as desired. Note that, in each method, it is preferable to add an organic solvent to each compositions as required to adjust the viscosities of the compositions and thereby control the workability when impregnating them in the fiber base material or coating, spraying, or casting them on the support.

As the support which is used at this time, a polyethylene terephthalate film, polypropylene film, polyethylene film, polycarbonate film, polyethylene naphthalate film, polyarylate film, nylon film, or other resin film or copper foil, aluminum foil, nickel foil, chrome foil, gold foil, silver foil, or other metal foil may be mentioned. These may be applied to either just one surface of the prepreg or to both surfaces.

The thickness of the prepreg of the present invention is not particularly limited, but is preferably made a thickness such that the thickness of the platable layer becomes preferably 1 to 10 μm, more preferably 1.5 to 8 μm, furthermore preferably 2 to 5 μm and, further, the thickness of the adhesive layer becomes preferably 10 to 100 μm, more preferably 10 to 80 μm, furthermore preferably 15 to 60 μm.

When producing the prepreg of the present invention, as the method of coating the platable layer-use resin composition and the curable epoxy composition, dip coating, roll coating, curtain coating, die coating, slit coating, gravure coating, etc. may be mentioned.

Further, in the prepreg of the present invention, in the same way as the above-mentioned film and laminated film of the present invention, the resin composition which forms the prepreg is preferably in an uncured or a semicured state.

Further, the prepreg of the present invention which is obtained in the above way may be made into a cured article by heating and curing it.

The curing temperature is usually 30 to 400° C., preferably 70 to 300° C., more preferably 100 to 200° C. Further, the curing time is 0.1 to 5 hours, preferably 0.5 to 3 hours. The method of heating is not particularly limited. For example, an electric oven etc. may be used for this.

(Laminate)

The laminate of the present invention is one obtained by laminating the above-mentioned film, laminated film, or prepreg of the present invention on a base material. The laminate of the present invention may be one obtained by laminating at least the above-mentioned film, laminated film, or prepreg of the present invention, but is preferably one obtained by laminating a substrate which has a conductor layer on its surface and an electrical insulating layer which is comprised of the film, laminated film, or prepreg of the present invention.

The substrate which has a conductor layer on its surface is one which has a conductor layer on the surface of an electrical insulating substrate. The electrical insulating substrate is formed by curing a resin composition which contains a known electrical insulating material (for example, alicyclic olefin polymer, epoxy resin, maleimide resin, (meth)acrylic resin, diallyl phthalate resin, triazine resin, polyphenylene ether, glass, etc.). The conductor layer is not particularly limited, but is usually a layer which includes wiring which are formed by a conductive metal or other conductor and may further include various circuits as well. The configurations, thicknesses, etc. of the wiring and circuits are not particularly limited. As specific examples of a substrate which has a conductor layer on its surface, a printed circuit board, silicon wafer board, etc. may be mentioned. The substrate which has a conductor layer on its surface has a thickness of usually 10 μm to 10 mm, preferably 20 μm to 5 mm, more preferably 30 μm to 2 mm.

The substrate which has a conductor layer on its surface used in the present invention is preferably pretreated on the surface of the conductor layer so as to improve the adhesion with the electrical insulating laver. As the method of pretreatment, known art can be used without particular limitation. For example, if the conductor layer is comprised of copper, the oxidizing method of bringing a strong alkaline oxidizing solution into contact with the conductor layer surface to form a layer of copper oxide on the conductor surface and roughen it, the method of oxidizing the conductor layer surface by the previous method, then reducing it by sodium borohydride, formalin, etc., the method of depositing plating on the conductor layer to roughen it, the method of bringing an organic acid into contact with the conductor layer to dissolve the grain boundaries of the copper and roughen the layer, the method of forming a primer layer on the conductor layer by a thiol compound, silane compound, etc. and the like may be mentioned. Among these, from the viewpoint of the ease of maintaining the shapes of fine wiring patterns, the method of bringing an organic acid into contact with the conductor layer to dissolve the grain boundaries of the copper and roughen the layer and the method of using thiol compounds or silane compounds etc. to form a primer layer are preferable.

The laminate of the present invention may be produced by hot press bonding, on a substrate which has a conductor layer on its surface, the above-mentioned film of the present invention (that is, the shaped article which is obtained by forming the curable epoxy composition of the present invention into a sheet shape or film shape), laminated film of the present invention (that is, the shaped article of the sheet shape or film shape which is comprised of an adhesive layer of the curable epoxy composition of the present invention and a platable layer), or prepreg of the present invention (the composite shaped article which is comprised of the film of the present invention and a fiber base material or composite shaped article which is comprised of the laminated film of the present invention and the fiber base material) of the present invention.

As the method of hot pressing, the method of superposing the shaped article with a support or composite shaped article on a substrate to contact the conductor layer and using a press laminator, press machine, vacuum laminator, vacuum press, roll laminator, or other pressure device for hot pressing (lamination) may be mentioned. By hot pressing, it is possible to join the conductor layer on the substrate surface and the shaped article or composite shaped article with substantially no clearance at their interface.

The temperature of the hot bonding operation is usually 30 to 250° C., preferably 70 to 200° C., the pressure which is applied is usually 10 kPa to 20 MPa, preferably 100 kPa to 10 MPa, and the pressing time is usually 30 seconds to 5 hours, preferably 1 minute to 3 hours. Further, the hot bonding is preferably performed under reduced pressure to improve burying the wiring patterns into the insulating adhesive film or prepreg or to prevent the formation of bubbles. The pressure of the reduced pressure for performing the hot bonding is usually 100 kPa to 1 Pa, preferably 40 kPa to 10 Pa.

(Cured Article)

The cured article of the present invention is one obtained by curing the curable epoxy composition of the present invention and includes any of the film, laminated film, prepreg, and laminate of the present invention which is comprised of the above composition and has been cured. The curing can be performed by suitably heating the curable epoxy composition or film etc. of the present invention under the later explained curing conditions.

For example, the laminate of the present invention can be made a cured article by treatment to cure the film, laminated film, or prepreg of the present invention forming the same. The curing is usually performed by heating the substrate as a whole on which the film, laminated film, or prepreg of the present invention is formed on the conductor layer. The curing can be performed simultaneously with the above-mentioned hot press bonding operation. Further, the hot press bonding operation may be performed under conditions where curing does not occur, that is, at a relatively low temperature and short time, and then curing performed.

Further, for the purpose of improving the flatness of the electrical insulating layer or the purpose of increasing the thickness of the electrical insulating layer, it is also possible to bond two or more films, laminated films, or prepregs of the present invention on a conductor layer of a substrate for lamination.

The curing temperature is usually 30 to 400° C., preferably 70 to 300° C., more preferably 100 to 200° C. Further, the curing time is 0.1 to 5 hours, preferably 0.5 to 3 hours. The method of heating is not particularly limited. For example, an electrical oven etc. may be used for this.

(Composite)

The composite of the present invention is comprised of the cured article of the present invention on the surface of which a conductor layer is formed.

For example, when the laminate of the present invention forms a multilayer board, the composite of the present invention is comprised of a laminate on the electrical insulating layer of which a still other conductor layer is formed. As this conductor layer, a metal plating or metal foil may be used. As the metal plating material, gold, silver, copper, rhodium, palladium, nickel, tin, etc. may be mentioned. As the metal foil, one which is used as the support of the above-mentioned film, laminated film, or prepreg may be mentioned. Note that, in the present invention, the method of using a metal plating as a conductor layer is preferable from the viewpoint that fine micro wiring can be formed. Below, the method of production of the composite of the present invention will be explained illustrating a multilayer circuit board which uses a metal plating as a conductor layer as one example of the composite of the present invention.

First, the laminate is formed with via holes or through holes which pass through the electrical insulating layer. The via holes are formed for connecting the different conductor layers which form a multilayer circuit board when forming a multilayer circuit board. The via holes and through holes can be formed by chemical treatment such as photolithography or by physical treatment such as drilling, laser irradiation, and plasma etching. Among these methods, the method using a laser (CO₂ gas laser, excimer laser, UV-YAG laser, etc.) enables fine via holes to be formed without causing a drop in the characteristics of the electrical insulating layer, so this is preferred.

Next, the surface of the electrical insulating layer of the laminate (that is, the cured article of the present invention) is roughened by surface roughening treatment. The surface roughening treatment is performed so as to enhance the adhesion with the conductor layer which is formed on the electrical insulating layer.

The surface average roughness Ra of the electrical insulating layer is preferably 0.05 μm or more and less than 0.5 μm, more preferably 0.06 μm or more and 0.3 μm or less, while the surface 10-point average roughness Rzjis is preferably 0.3 μm or more and less than 5 μm, more preferably 0.5 μm or more and 3 μm or less. Note that, in this Description, Ra is the arithmetic average roughness which is shown in JIS B0601-2001, while the surface 10-point average roughness Rzjis is the 10-point average roughness which is shown in JIS B0601-2001 Annex 1.

The method of surface roughening treatment is not particularly limited, but the method of bringing the surface of the electrical insulating layer into contact with an oxidizing compound etc. may be mentioned. As the oxidizing compound, an inorganic oxidizing compound or organic oxidizing compound or other known compound which has an oxidizing ability may be mentioned. From the ease of control of the surface average roughness of the electrical insulating layer, use of an inorganic oxidizing compound or organic oxidizing compound is particularly preferable. As the inorganic oxidizing compound, a permanganate, chromic acid anhydride, dichromate, chromate, persulfate, active manganese dioxide, osmium tetraoxide, hydrogen peroxide, periodide, etc. may be mentioned. As the organic oxidizing compound, dicumyl peroxide, octanoyl peroxide, m-chloroperbenzoate, peracetate, ozone, etc. may be mentioned.

The method of using an inorganic oxidizing compound or organic oxidizing compound to roughen the surface of the electrical insulating layer is not particularly limited. For example, the method of dissolving the above oxidizing compound in a solvent which can dissolve it so as to prepare an oxidizing compound solution and bringing this into contact with the surface of the electrical insulating layer may be mentioned. The method of bringing the oxidizing compound solution into contact with the surface of the electrical insulating layer is not particularly limited, but, for example, the dipping method of dipping the electrical insulating layer in the oxidizing compound solution, the buildup method of utilizing the surface tension of the oxidizing compound solution to place the oxidizing compound solution on the electrical insulating layer, the spraying method of spraying the oxidizing compound solution on the electrical insulating layer, or any other method may also be used. By performing the surface roughening treatment, it is possible to improve the adhesion of the electrical insulating layer with the conductor layer and other layers.

The temperature and the time by which these oxidizing compound solutions are brought into contact with the surface of the electrical insulating layer may be freely set by considering the concentration and type of the oxidizing compound, method of contact, etc., but the temperature is usually 20 to 100° C., preferably 30 to 90° C., while the time is usually 0.5 to 60 minutes, preferably 1 to 40 minutes.

Note that, to remove the oxidizing compound after the surface roughening treatment, the surface of the electrical insulating layer after the surface roughening treatment is washed with water. Further, when a substance which cannot be washed off by just water is deposited on the surface, the surface is further washed by a washing solution which can dissolve that substance or another compound is brought into contact with the surface to convert the substance into one which can be dissolved in water and then the surface is washed by water. For example, when bringing an aqueous solution of potassium permanganate or an aqueous solution of sodium permanganate or other alkali aqueous solution into contact with the electrical insulating layer, to remove the film of manganese dioxide which is formed, it is possible to using a mixed solution of hydroxylamine sulfate and sulfuric acid or other acidic aqueous solution to neutralize/reduce the surface, then wash it by water.

Next, after the electrical insulating layer of the laminate is treated to roughen its surface, a conductor layer is formed on the surface of the electrical insulating layer and the inside wall surfaces of the via holes or through holes.

The method of formation of the conductor layer is performed, from the viewpoint of enabling formation of a conductor layer which is excellent in adhesion, using the electroless plating method.

For example, when using electroless plating to form a conductor layer, first, before forming a metal thin layer on the surface of the electrical insulating layer, the general practice has been to deposit silver, palladium, zinc, cobalt, or another catalyst nuclei on the electrical insulating layer. The method of depositing catalyst nuclei on the electrical insulating layer is not particularly limited, but, for example, the method of dipping the article in a solution obtained by dissolving silver, palladium, zinc, cobalt, or other metal compounds or their salts or complexes in water, alcohol, chloroform or another organic solvent in 0.001 to 10 wt % in concentration (as desired, also possibly including an acid, alkali, complexing agent, reducing agent, etc.), then reducing the metal etc. may be mentioned.

As the electroless plating solution which is used in the electroless plating, a known self-catalyst type electroless plating solution may be used. It is not particularly limited in the type of metal, the type of reducing agent, the type of complexing agent, the concentration of hydrogen ions, the concentration of dissolved oxygen, etc. which are contained in the plating solution. For example, an electroless copper plating solution which contains ammonium hypophosphite, hypophosphoric acid, ammonium borohydride, hydrazine, formalin, etc. as a reducing agent; an electroless nickel-phosphorus plating solution which contains sodium hypophosphite as a reducing agent; an electroless nickel-boron plating solution which contains dimethylamineborane as a reducing agent; an electroless palladium plating solution; an electroless palladium-phosphorus plating solution which contains sodium hypophosphite as a reducing agent; an electroless gold plating solution; an electroless silver plating solution; an electroless nickel-cobalt-phosphorus plating solution which contains sodium hypophosphite as a reducing agent, or other electroless plating solution can be used.

After forming the metal thin layer, the substrate surface may be brought into contact with a rustproofing agent to make it rustproof. Further, after forming the metal thin layer, the metal thin layer may be heated to raise the adhesiveness. The heating temperature is usually 50 to 350° C., preferably 80 to 250° C. Note that, at this time, the heating may be performed under pressed conditions. As the pressing method at this time, for example, the method of using a hot press, a pressurizing and heating roll, and other physical pressing means may be mentioned. The pressure which is applied is usually 0.1 to 20 MPa, preferably 0.5 to 10 MPa. If this range, high adhesion can be secured between the metal thin layer and the electrical insulating layer.

The thus formed metal thin layer is formed with a plating-use resist pattern and the plating is further grown over it by electroplating or other wet plating (thickening plating). Next, the resist is removed and the surface is further etched to etch the metal thin layer into the pattern shapes and form the conductor layer. Therefore, the conductor layer which is formed by this method is usually comprised of the patterned metal thin layer and the plating which is grown over that.

Alternatively, when using metal foil instead of metal plating as the conductor layer which forms the multilayer circuit board, the following method can be used for production.

That is, first, the same procedure is followed as above to prepare a laminate which is comprised of an electrical insulating layer comprised of a film or prepreg and a conductor layer comprised of a metal foil. As such a laminate, when laminating and forming, it is preferable to make the curable epoxy composition a hardness enabling the required properties to be held and, due to this, it is preferable to prevent problems when subsequently working it or when forming a multilayer circuit board. In particular, it is preferable to form the laminate under a vacuum. Note that, a laminate which is comprised of such an electrical insulating layer comprised of a film or prepreg and a conductor layer comprised of a metal foil can, for example, be used for a printed circuit board by a known subtractive method.

Further, the prepared laminate is formed with, in the same way as above, via holes or through holes which pass through the electrical insulating layer, then the resin residue in the formed via holes is removed by desmearing the laminate which forms the through holes. The method of desmearing is not particularly limited, but for example the method of causing contact with a solution of permanganate or another oxidizing compound (desmearing solution) may be mentioned. Specifically, the laminate which is formed with the via holes can be dipped in a 60 to 80° C. aqueous solution which is adjusted to a concentration of sodium permanganate of 60 g/liter and a concentration of sodium hydroxide of 28 g/liters for 1 to 50 minutes with shaking so as to desmear it.

Next, after the laminate is desmeared, a conductor layer is formed at the inside wall surfaces of the via holes. The method of forming the conductor layer is not particularly limited, but it is possible to use either the electroless plating method or electroplating method. From the viewpoint of being able to form a conductor layer with a good adhesion, it is possible to use the electroless plating method in the same way as the method of forming a metal plating as the conductor layer.

Next, the inside wall surfaces of the via holes are formed with a conductor layer, then the metal foil is formed with a resist pattern for plating use and further electroplating or other wet plating is used to grow a plating (thick plating), then the resist is removed and the metal foil is further etched to pattern it by etching and form a conductor layer. Therefore, the conductor layer which is formed by this method is comprised of a patterned metal foil and plating which is grown on this.

By using the above obtained multilayer circuit board as the substrate for producing the above-mentioned laminate, hot pressing the above-mentioned shaped article or composite shaped article, and curing the same to form the electrical insulating layer and further forming a conductor layer on this in accordance with the above method, then repeating these steps, it is possible to form a further multilayer structure and thereby possible to obtain the desired multilayer circuit board.

The thus obtained composite of the present invention (and the multilayer circuit board of one example of the composite of the present invention) has an electrical insulating layer which is comprised of the curable epoxy composition of the present invention (the cured article of the present invention). The electrical insulating layer is excellent in electrical characteristics, heat resistance, wire embedding flatness, and flexibility, so the composite of the present invention (and the multilayer circuit board of one example of the composite of the present invention) can be suitably used for various applications.

(Substrate for Electronic Material Use)

The substrate for electronic material use of the present invention is comprised of the cured article or composite of the present invention explained above. The substrate for electronic material use of the present invention which is comprised of the cured article or composite of the present invention can be suitably used for a mobile phone, PHS, laptop PCs, PDAs (personal digital assistants), mobile TV phones, PCs, super computers, servers, routers, liquid crystal projectors, engineering work stations (EWS), pagers, word processors, televisions, viewfinder type or monitor direct viewing type video tape recorders, electronic handheld devices, electronic desktop computers, car navigation systems, POS terminals, devices provided with touch panels, and other various electronic equipment.

### EXAMPLES

Below, examples and comparative examples will be given to more specifically explain the present invention. Note that, in the examples, the “parts” and “%”, unless particularly indicated otherwise, are based on weight. The various types of properties were evaluated by the following methods.

(1) Number Average Molecular Weight (Mn) and Weight Average Molecular Weight (Mw) of Alicyclic Olefin Polymer

These were measured using tetrahydrofuran as a developing solvent and using gel permeation chromatography (GPC) and were found as values converted for polystyrene.

(2) Hydrogenation Ratio of Alicyclic Olefin Polymer

The ratio of the number of moles of the unsaturated bonds which were hydrogenated with respect to the number of moles of the unsaturated bonds in the polymer before the hydrogenation was found by measurement of the 400 MHz ¹H-NMR spectrum. This was used as the hydrogenation ratio.

(3) Desmearing Ability

A varnish which contains a glass filler and halogen-free epoxy compound was impregnated in glass fiber to obtain a core material. On the surfaces of the obtained core material, sheets of thickness 18 μm copper were bonded to prepare a thickness 0.8 mm, vertical 150 mm×horizontal 150 mm double-sided copper-clad substrate. The copper surfaces of this substrate were chemically etched to roughen them to obtain a surface roughness Pa of 400 nm. Next, on the two surfaces of this, film shaped article with a support was laminated, then just the support was peeled off. The result was heated in an air atmosphere at 180° C. for 30 minutes to cure the film shaped article and form resin layers comprised of film shaped cured article. The obtained laminate cured article was processed using a CO₂ laser apparatus (LC-2G212/2C, made by Hitachi Ltd.) under conditions of an output of 0.65W, three shots, a processing diameter (top surface) of 55 μm, and a processing diameter (bottom surface) of 50 μm to form holes for via hole use running through the resin layer to the copper surfaces so as to prepare a substrate for evaluation of the desmearing ability. This substrate was dipped in a 60° C. aqueous solution prepared to contain a swelling solution (“Swelling Dip Securiganth P”, made by Atotech, “Securiganth” is a registered trademark) 500 ml/liter and sodium hydroxide 3 g/liter for 15 minutes while shaking, then was rinsed. Next, this was dipped in an 80° C. aqueous solution prepared to contain an aqueous solution of permanganate (“Concentrate Compound CP”, made by Atotech) 640 ml/liter and sodium hydroxide concentration 40 g/liter for 20 minutes while shaking, then was rinsed. Next, the laminate cured article was dipped for 5 minutes in a 40° C. aqueous solution prepared to contain a hydroxylamine sulfate aqueous solution (“Reduction Securiganth P 500”, made by Atotech, “Securiganth” is a registered trademark) 100 ml/liter and sulfuric acid 35 ml/liter to neutralize and reduce it, then was rinsed. The bottom surfaces and cross-sections of the hole parts for via hole use in the thus obtained substrate were observed by an electron microscope (magnification: 5000×) and the desmearing ability was evaluated by the following evaluation criteria.

### (Evaluation Criteria)

A: No residual resin
B: Partial residual resin, but no practical problem
C: Residual resin presents

(4) Glass Transition Temperature

A width 6 mm, length 15.4 mm, thickness 40 μm piece was cut out from a film shaped cured article. Under conditions of a distance between support points of 10 mm and a temperature elevation rate of 10° C./minutes, a thermomechanical analyzer (TMA/SDTA840: made by Mettler Toledo) was used to find the glass transition temperature (Tg) of the film shaped cured article. A tangent was drawn to a curve around the glass transition temperature. Tg was found from the intersection of this tangent. If the Tg is 145° C. or more, the heat resistance can be evaluated as being excellent.

(5) Dielectric Tangent

A width 2.6 mm, length 80 mm, thickness 40 μm piece was cut out from a film shaped cured article, measured for dielectric tangent (tan δ) at 10 GHz using a resonant cavity perturbation method permittivity measurement apparatus. If the tan δ is 0.01 or less, the electrical characteristics can be evaluated as being excellent.

### Synthesis Example 1

Tetracyclo[6.5.0.1^{2,5}.0^{8,13}]trideca-3,8,10,12-tetraene (MTF) 80 molar parts, N-(4-phenyl)-(5-norbornene-2,3-dicarboxyimide) (NBPI) 20 molar parts, 1-hexene 1 molar part, anisole 590 molar parts, and a ruthenium-based polymerization catalyst constituted by 4-acetoxybenzylidene(dichloro) (4,5-dibromo-1,3-dimesityl-4-imidazolin-2-ylidene) (tricyclohexylphosphine) ruthenium (C1063, made by Wako Pure Chemical Industries) 0.015 molar part were charged into a nitrogen-substituted pressure-resistant glass reactor. While stirring, the mixture was subjected to a polymerization reaction at 80° C. for 1 hour to obtain a solution of a ring-opened polymer. This solution was measured by gas chromatography, whereupon it was confirmed substantially no monomers remained. The polymerization conversion rate was 99% or more.

Next, the solution of the obtained ring-opened polymer was charged into a nitrogen-substituted autoclave equipped with a stirrer, then the mixture was stirred at 150° C. under a hydrogen pressure of 7 MPa for 5 hours to cause a hydrogenation reaction. The obtained hydrogenated reaction solution was concentrated to obtain a solution of alicyclic olefin polymer (1) (solid content concentration 55.5%). The obtained alicyclic olefin polymer (1) had a weight average molecular weight of 50,000, number average molecular weight of 20,000, and hydrogenation rate of 97%.

### Example 1

(Preparation of Curable Epoxy Composition)

A polyvalent epoxy compound (A) constituted by a phenol novolac type epoxy compound which has a dicyclopentadiene structure (product name “Epicion HP7200HH”, made by DIC, epoxy equivalent: 280) 90 parts, a polyvalent glycidyl ester compound (B) constituted by phthalic acid diglycidyl ester (product name “Denacol EX-721”, made by Nagase Chemtex, epoxy equivalent: 154) 10 parts, an active ester compound (C) constituted by an active ester compound (product name “Epiclon HPC-800065T”, nonvolatile content 65% toluene solution, made by DIC, active ester group equivalent: 223) 130.7 parts (converted to active ester compound: 85 parts), a solution of alicyclic olefin polymer (1) obtained in Synthesis Example 1, 18.2 parts (converted to alicyclic olefin polymer (1): 10 parts), a filler constituted by silica (product name “SC2500-SXJ”, average particle size: 0.5 μm, treated on surface by aminosilane coupling agent, made by Admatechs) 365 parts, an antiaging agent constituted by a hindered phenol-based antioxidant (product name “Irganox 3114”, made by BASF) 1.5 parts, and anisole 110 parts were mixed and stirred by a planetary mixer for 3 minutes.

Furthermore, to this, a curing accelerator constituted by a solution of 30% 1-benzyl-2-phenylimidazole dissolved in anisole 3 parts (converted to curing accelerator: 0.9 part) was mixed and stirred by a planetary mixer for 5 minutes to obtain a varnish of a curable epoxy composition.

(Preparation of Film Shaped Article)

Next, the above obtained varnish of the curable epoxy composition was applied by a die coater on a vertical 300 mm×horizontal 300 mm size, thickness 38 μm, surface average roughness Ra 0.08 μm polyethylene terephthalate film (support: Lumirror (registered trademark) T60, made by Toray Industries Inc.), then dried in a nitrogen atmosphere at 80° C. for 10 minutes to obtain a film shaped article of thickness 43 μm resin composition on a support. The obtained film shaped article was used in accordance with the above methods to prepare a substrate for evaluation of the desmearing ability and evaluate the desmearing ability. The results are shown in Table 1.

(Preparation of Film Shaped Cured Article)

Next, a piece which was cut out from the thus obtained film shaped article of the curable epoxy composition was placed on a thickness 10 μm copper foil. This was set, in the state with the support attached, so that the curable epoxy composition became the inside. A vacuum laminator which was provided with heat resistant rubber press plates at the top and bottom was used to reduce the pressure to 200 Pa and hot press bond the laminate at a temperature of 110° C. and a pressure of 0.1 MPa for 60 seconds, the support was peeled off, then the laminate was heated and cured at 180° C. for 120 minutes in the air. After curing, the copper foil of the cured resin with the copper foil was dissolved in a 1 mol/liter ammonium persulfate aqueous solution to obtain a film shaped cured article. The obtained film shaped cured article was used in accordance with the above methods to measure the glass transition temperature and dielectric tangent. The results are shown in Table 1.

### Examples 2 to 4

Except for changing the types and amounts of the polyvalent epoxy compound and polyvalent glycidyl ester compound and the amount of the active ester compound in accordance with the compositions of the curable epoxy compositions in the examples shown in Table 1, the same procedures were followed as in Example 1 to obtain varnishes of curable epoxy compositions, film shaped articles, and film shaped cured articles and to measure and evaluate them. The results are shown in Table 1.

Note that, in the polyvalent epoxy compounds of Table 1, the phenol novolac type epoxy compound having a biphenyl structure is product name “NC3000-H” (made by Nippon Kayaku, epoxy equivalent: 290) and the bisphenol A type epoxy compound is product name “jER828EL” (made by Mitsubishi Chemical, epoxy equivalent: 189), while in the polyvalent glycidyl ester compounds, the terephthalic acid diglycidyl ester is product name “Denacol EX-711” (made by Nagase ChemteX, epoxy equivalent: 147).

### Comparative Examples 1 to 4

Except for changing the types and amounts of the polyvalent epoxy compound and polyvalent glycidyl ester compound and the amount of the active ester compound in accordance with the compositions of the curable epoxy compositions in the comparative examples shown in Table 1, the same procedures were followed as in Example 1 to obtain varnishes of curable epoxy compositions, film shaped articles, and film shaped cured articles and to measure and evaluate them. The results are shown in Table 1.

Table 1

TABLE 1

| Examples | | | | Comparative Examples | | | |
|---|---|---|---|---|---|---|---|
| 1 | 2 | 3 | 4 | 1 | 2 | 3 | 4 |

Composition of curable epoxy composition (parts)

| | | | | | | | | | |
|---|---|---|---|---|---|---|---|---|---|
| Polyvalent | Phenol novolac type epoxy compound | 90 | 50 | 0 | 90 | 100 | 0 | 90 | 0 |
| epoxy | which has dicyclopentadiene structure | | | | | | | | |
| compound | Phenol novolac type epoxy compound | 0 | 0 | 90 | 0 | 0 | 0 | 0 | 0 |
| | which has biphenyl structure | | | | | | | | |
| | Bisphenol A type epoxy compound | 0 | 0 | 0 | 0 | 0 | 0 | 10 | 100 |
| Polyvalent | Phthalic acid diglycidyl ester | 10 | 50 | 10 | 0 | 0 | 100 | 0 | 0 |
| glycidyl | Terephthalic acid diglycidyl ester | 0 | 0 | 0 | 10 | 0 | 0 | 0 | 0 |
| ester | | | | | | | | | |
| compound | | | | | | | | | |

| | | | | | | | | |
|---|---|---|---|---|---|---|---|---|
| Active ester compound | 85 | 88 | 83 | 86 | 79.2 | 144 | 83 | 117 |
| Alicyclic olefin polymer | 10 | 10 | 10 | 10 | 10 | 10 | 10 | 10 |
| Ratio of polyvalent glycidyl ester compound in | 10% | 50% | 10% | 10% | 0% | 100% | 0% | 0% |
| epoxy compound | | | | | | | | |
| Equivalent ratio of epoxy compound/active ester | 1.01 | 1.01 | 1.01 | 1.01 | 1.01 | 1.01 | 1.01 | 1.01 |
| compound | | | | | | | | |

Results of evaluation

| | | | | | | | | |
|---|---|---|---|---|---|---|---|---|
| Desmearing ability | B | A | B | B | C | A | C | C |
| Glass transition temperature (Tg) | 162° C. | 151° C. | 146° C. | 161° C. | 168° C. | 134° C. | 160° C. | 144° C. |
| Dielectric tangent (Tan δ) | 0.0058 | 0.0057 | 0.0057 | 0.0057 | 0.0059 | 0.0052 | 0.0062 | 0.0048 |

As shown in Table 1, according to the curable epoxy composition of the present invention, a film shaped cured article which is excellent in desmearing ability, electrical characteristics, and heat resistance is obtained. Therefore, according to the above composition, it will be understood that an electrical insulating layer which has such excellent characteristics can be formed.

### Synthesis Example 2

As a first polymerization stage, 5-ethylidene-bicyclo[2.2.1]hept-2-ene (below, abbreviated as “EdNB”) 35 molar parts, 1-hexene 0.9 molar part, anisole 340 molar parts, and a ruthenium-based polymerization catalyst constituted by 4-acetoxybenzylidene(dichloro)(4,5-dibromo-1,3-dimesityl-4-imidazolin-2-ylidene)(tricyclohexylphosphine)ruthenium (C1063, made by Wako Pure Chemical Industries) 0.005 molar part were charged into a nitrogen-substituted pressure-resistant glass reactor and subjected to a polymerization reaction under stirring at 80° C. for 30 minutes to obtain a solution of a norbornene-based ring-opened polymer.

Next, as a second polymerization stage, to the solution which was obtained at the first polymerization stage, tetracyclo[9.2.1.0^{2,10}.0^{3,8}]tetradeca-3,5,7,12-tetraene (methanotetrahydrofluorene) 45 molar parts, bicyclo[2.2.1]hept-2-ene-5,6-dicarboxylic acid anhydride 20 molar parts, anisole 250 molar parts, and 0.01 molar part of C1063 were added and subjected to a polymerization reaction under stirring at 80° C. for 1.5 hours to obtain a solution of a norbornene-based ring-opened polymer. This solution was measured by gas chromatography, whereupon it was confirmed that substantially no monomer remained. The polymerization conversion rate was 99% or more.

Next, a nitrogen-substituted autoclave equipped with a stirrer was charged with the solution of the obtained ring-opened polymer, 0.03 molar part of C1063 was added, and the mixture was stirred at 150° C. under a hydrogen pressure of 7 MPa for 5 hours to cause a hydrogenation reaction and obtain a solution of a hydrogenate of the norbornene-based ring-opened polymer constituted by the alicyclic olefin polymer (2). The obtained alicyclic olefin polymer (2) had a weight average molecular weight of 60,000, number average molecular weight of 30,000, and molecular weight distribution of 2. Further, the hydrogenation rate was 95%, while the content of the repeating units which have carboxylic acid anhydride groups was 20 mol %. The solid content concentration of the solution of the alicyclic olefin polymer (2) was 22%.

### Example 5

(Platable Layer-Use Resin Composition)

The solution of the alicyclic olefin polymer (2) which was obtained in Synthesis Example 2, 454 parts (converted to alicyclic olefin polymer (2): 100 parts), a phenol novolac type epoxy compound which has a dicyclopentadiene structure (“Epicion HP7200L”, made by DIC, “Epiclon”is a registered trademark) 36 parts, an inorganic filler constituted by silica (“Admafine SO-C1”, made by Admatechs, average particle size 0.25 μm, “Admafine” is a registered trademark) 24.5 parts, an antiaging agent constituted by tris(3,5-di-t-butyl-4-hydroxybenzyl)-isocyanulate (“Irganox 3114”, made by Ciba Specialty Chemicals) 1 part, an ultraviolet absorber constituted by 2-[2-hydroxy-3,5-bis(α,α-dimethylbenzyl)phenyl]-2H-benzotriazole 0.5 part, and a curing accelerator constituted by 1-benzyl-2-phenylimidazole 0.5 part were mixed in anisole and mixed to give a concentration of the compounding agents of 16% so as to obtain a varnish of the platable layer-use resin composition.

(Preparation of Film Composite)

The varnish of the platable layer-use resin composition which was obtained above was applied on a thickness 38 μm polyethylene terephthalate film (support) by using a wire bar, then was dried in a nitrogen atmosphere at 80° C. for 10 minutes to obtain a film with a support on which a thickness 3 μm platable layer comprised of an uncured platable layer-use resin composition was formed.

Next, the surface of the film with the support on which the platable layer comprised of the platable layer-use resin composition was formed was coated with the varnish of the curable epoxy composition which was obtained in Example 1 by using a doctor blade (made by Tester Sangyo Co., Ltd) and an auto film applicator (made by Tester Sangyo Co., Ltd), then was dried in a nitrogen atmosphere at 80° C. for 10 minutes to obtain a laminated film with the support on which a total thickness 43 pm platable layer and adhesive layer were formed. The laminated film with the support was formed by the support, the platable layer comprised of the platable layer-use resin composition, and the adhesive layer comprised of the curable epoxy composition in that order.

(Preparation of Laminate Cured Article)

Next, separate from the above, a varnish which contains glass filler and a halogen-free epoxy resin was impregnated in glass fibers to obtain a core material. On the surfaces of this, thickness 18 μm copper was bonded to obtain a thickness 0.8 mm, 150 mm square (vertical 150 mm and horizontal 150 mm) two-sided copper-clad substrate. On the surfaces of this, conductor layers with interconnect widths and interconnect pitches of 50 μm and thicknesses of 30 μm and with surfaces microetched by contact with an organic acid were formed to obtain an inside layer substrate.

At the two surfaces of the inside layer substrate, the above obtained laminated film with the support cut into 150 mm square pieces were bonded with the surfaces at the curable epoxy composition sides becoming the insides, then the laminate was pressed by primary pressing. The primary pressing was hot press bonding by a vacuum laminator which is provided with press plates made of heat resistant rubber at the top and bottom under a reduced pressure of 200 Pa at a temperature 110° C. with a pressure of 0.1 MPa for 90 seconds. Furthermore, a hydraulic press apparatus which is provided with metal press plates at the top and bottom was used for hot press bonding at a press bonding temperature of 110° C. and 1 MPa for 90 seconds. Next, the supports were peeled off to obtain a laminate of a resin layer which was comprised of the curable epoxy composition and the platable layer-use resin composition and the inside layer substrate. Furthermore, the laminate was allowed to stand in an air atmosphere at 180° C. for 60 minutes to make the resin layer cure and form an electrical insulating layer on the inside layer substrate.

(Swelling Treatment Step)

The obtained laminate cured article was dipped while shaking in a 60° C. aqueous solution which was prepared to contain a swelling solution (“Swelling Dip Securiganth P”, made by Atotech, “Securiganth” is a registered trademark) 500 ml/liter and sodium hydroxide 3 g/liter for 15 minutes, then was rinsed.

(Oxidizing Treatment Step)

Next, the laminate cured article was dipped while shaking in an 80° C. aqueous solution which was prepared to contain an aqueous solution of permanganate (“Concentrate Compact CP”, made by Atotech) 640 ml/liter and a concentration of sodium hydroxide of 40 g/liter for 20 minutes, then was rinsed.

(Neutralizing/Reduction Treatment Step)

Next, the laminate cured article was dipped in a 40° C. aqueous solution which was prepared to contain an aqueous solution of hydroxylamine sulfate (“Reduction Securiganth P 500”, made by Atotech, “Securiganth” is a registered trademark) 100 ml/liter and sulfuric acid 35 ml/liter for 5 minutes to neutralize and reduce it, then was rinsed.

(Cleaner/Conditioner Step)

Next, the laminate cured article was dipped in a 50° C. aqueous solution which was prepared to contain a cleaner/conditioner aqueous solution (“Alcup MCC-6-A”, made by Uyemura & Co., Ltd. “Alcup” is a registered trademark) of a concentration of 50 ml/liter for 5 minutes to treat it with the cleaner and conditioner. Next, the laminate was dipped in 40° C. rinsing water for 1 minute, then was rinsed.

(Soft Etching Step)

Next, the laminate cured article was dipped in an aqueous solution which was prepared to contain a sulfuric acid concentration of 100 g/liter and sodium persulfate of 100 g/liter for 2 minutes to be soft etched, then was rinsed.

(Pickling Step)

Next, the laminate cured article was dipped in an aqueous solution which was prepared to contain a sulfuric acid concentration of 100 g/liter for 1 minute to be pickled, then was rinsed.

(Catalyst Imparting Step)

Next, the laminate cured article was dipped in a 60° C. Pd salt-containing plating catalyst aqueous solution which was prepared to contain Alcup Activator MAT-1-A (product name, made by Uyemura & Co., Ltd. “Alcup” is a registered trademark) 200 ml/liter, Alcup Activator MAT-1-B (product name, made by Uyemura & Co., Ltd. “Alcup” is a registered trademark) 30 ml/liter, and sodium hydroxide 0.35 g/liter for 5 minutes, then was rinsed.

(Activation Step)

Next, the laminate cured article was dipped in an aqueous solution which was prepared to contain Alcup Reducer MAB-4-A (product name, made by Uyemura & Co., “Alcup” is a registered trademark) 20 ml/liter and Alcup Reducer MAB-4-B (product name, made by Uyemura & Co., Ltd. “Alcup” is a registered trademark) 200 ml/liter at 35° C. for 3 minutes to reduce the plating catalyst, then was rinsed.

(Accelerator Treatment Step)

Next, the laminate cured article was dipped in an aqueous solution which was prepared to contain Alcup Accelerator MEL 3-A (product name, made by Uyemura & Co., Ltd. “Alcup” is a registered trademark) 50 ml/liter at 25° C. for 1 minute.

(Electroless Plating Step)

The thus obtained laminate cured article was dipped in an electroless copper plating solution which was prepared to contain Thru-Cup PEA-6-A (product name, made by Uyemura & Co., Ltd. “Thru-Cup” is a registered trademark) 100 ml/liter, Thru-Cup PEA-6-B-2X (product name, made by Uyemura & Co. Ltd.) 50 ml/liter, Thru-Cup PEA-6-C (product name, made by Uyemura & Co. Ltd.) 14 ml/liter, Thru-Cup PEA-6-D (product name, made by Uyemura & Co. Ltd.) 15 ml/liter, Thru-Cup PEA-6-E (product name, made by Uyemura & Co. Ltd.) 50 ml/liter, and 37 wt % formalin aqueous solution 5 ml/liter, while blowing in air, at a temperature of 36° C. for 20 minutes for electroless copper plating so as to form an electroless plating film on the laminate cured article surface (surface of platable layer comprised of platable layer-use resin composition).

Next, the laminate cured article which was formed with the electroless plating film was dipped in a corrosion inhibiting solution which was prepared to contain AT-21 (product name, made by Uyemura & Co. Ltd.) in 10 ml/liter at room temperature for 1 minute, then was rinsed. Furthermore, this was dried to prepare a corrosion-resistant treated laminate. This corrosion-resistant treated laminate cured article was annealed in an air atmosphere at 150° C. for 30 minutes.

The annealed laminate cured article was electroplated with copper to form a thickness 18 μm electroplated copper layer. Next, the laminate cured article was heat treated at 180° C. for 60 minutes to thereby obtain a two-sided two-layer multilayer printed circuit board comprised of a laminate cured article on which circuits are formed by conductor layers which are comprised of the metal thin film layers and electroplated copper layers.

1-12. (canceled)

13. A curable epoxy composition comprising a polyvalent epoxy compound (A) which has a condensed polycyclic structure and/or biphenyl structure (however, excluding an aromatic and/or alicyclic polyvalent glycidyl ester compound (B)), an aromatic and/or alicyclic polyvalent glycidyl ester compound (B), and an active ester compound (C).

14. The curable epoxy composition according to claim 13 wherein the ratio of content of the aromatic and/or alicyclic polyvalent glycidyl ester compound (B) is 5 to 75 wt % in the total 100 wt % of epoxy compounds which are used.

15. The curable epoxy composition according to claim 13 wherein the polyvalent epoxy compound (A) which has a condensed polycyclic structure and/or biphenyl structure is a phenol novolac type epoxy compound which has a condensed polycyclic structure and/or biphenyl structure.

16. The curable epoxy composition according to claim 13 wherein the aromatic and/or alicyclic polyvalent glycidyl ester compound (B) is an o-phthalic acid diglycidyl ester and/or terephthalic acid diglycidyl ester.

17. The curable epoxy composition according to claim 13 further comprising an alicyclic olefin polymer which contains an aromatic ring and/or hetero atom and does not have reactivity with an epoxy group.

18. A film which is comprised of the curable epoxy composition according to claim 13.

19. A laminated film having an adhesive layer which is comprised of the curable epoxy composition according to claim 13 and a platable layer which is comprised of a platable layer-use resin composition.

20. A prepreg which is comprised of the film according to claim 18, and a fiber substrate.

21. A laminate obtained by laminating, on a base material, the film according to claim 18.

22. A cured article obtained by curing the curable epoxy composition according to claim 13.

23. A cured article obtained by curing the film according to claim 18.

24. A cured article obtained by curing the laminated film according to claim 19.

25. A cured article obtained by curing the prepreg according to claim 20.

26. A cured article obtained by curing the laminate according to claim 21.

27. A composite obtained by forming a conductor layer on the surface of the cured article according to claim 22.

28. A substrate for an electronic material including, as a component material, the cured article according to claim 22.

29. A substrate for an electronic material including, as a component material, the composite according to claim 27.
